(19) United States
(12) Patent Application Publication
(10) Pub. No.: US 2007/0145440 A1
(43) Pub. Date: Jun. 28, 2007

(54) CMOS Image Sensor and Method for Fabricating the Same

(76) Inventor: Keun Hyuk Lim, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/615,125

(22) Filed: Dec. 22, 2006

(30) Foreign Application Priority Data
Dec. 28, 2005 (KR) 10-2005-0132689

(51) Int. Cl. H01L 31/113

(52) U.S. Cl. 257/291

(57) ABSTRACT

A CMOS image sensor and a method of fabricating the same are provided. The CMOS image sensor includes a semiconductor substrate having a photodiode region and a transistor region defined therein, first and second gate electrodes formed on the photodiode region of the semiconductor substrate with a gate insulating layer interposed therebetween, the first and second electrodes connected in a “⊂” shape spaced a predetermined interval from each other, a first conductivity type diffusion region formed in the photodiode region including between the first and second gate electrodes, spacer insulating layers formed on sidewalls of the first and second gate electrodes, and a floating diffusion region formed in the transistor region.

### RELATED APPLICATION(S)

This application claims priority under 35 U.S.C. §119(e) of Korean Patent Application No. 10-2005-0132689 filed Dec. 28, 2005, which is incorporated herein by reference in its entirety.

### FIELD OF THE INVENTION

The present invention relates to a complementary metal oxide semiconductor (CMOS) image sensor.

### BACKGROUND OF THE INVENTION

In general, an image sensor is a semiconductor device that converts an optical image to an electric signal. The image sensor is classified as a charge coupled device (CCD) or a CMOS image sensor.

The CCD includes a plurality of photodiodes PDs, a plurality of vertical charge coupled devices (VCCDs), a horizontal charge coupled device (HCCD) and a sense amplifer. The PDs converting light signals to electric signals are arranged in a matrix form. The VCCDs are formed vertically between the photodiodes to transmit charges generated in each of the photodiodes in a vertical direction. The HCCD horizontally transmits the charges transmitted from the VCCD. The sense amplifier senses the charges transmitted in a horizontal direction to output electric signals.

However, the CCD not only has a complicated driving method and high power consumption but also requires a plurality of photolithography processes.

Also, it is not possible to integrate a control circuit, signal processing circuit, and an analog/digital converting circuit (A/D convert) into a single charge coupled device chip.

Nowadays, to overcome drawbacks of the CCD, the CMOS image sensor is widely used as a next-generation image sensor.

In the CMOS image sensor, MOS transistors corresponding to the number of unit pixels are formed in a semiconductor substrate by using a CMOS technology. In the CMOS technology, a control circuit and a signal processing circuit are used as a peripheral circuit. Additionally, the CMOS image sensor is a device employing a switching method. In the switching method, the MOS transistors sequentially detect the output of each unit pixel.

That is, the CMOS image sensor includes photodiodes and MOS transistors in the unit pixel, and sequentially detects an electric signal of each unit pixel to display an image.

Since the CMOS image sensor uses the CMOS technology, there are advantages of low power consumption and a small number of photolithography processes.

Additionally, the CMOS image sensor can integrate the control circuit, the signal processing circuit, the analog/digital converting circuit into a single CMOS image sensor chip such that miniaturization of a product can be easily achieved.

Moreover, the CMOS image sensor is widely used in applications such as a digital still camera and a digital video camera.

The CMOS image sensor is classified as a 3T-type, a 4T-type, or a 5T-type according to the number of transistors formed in a unit pixel. For example, the 3T-type includes one photodiode and three transistors, and the 4T-type includes one photodiode and four transistors.

An equivalent circuit and a layout for a unit pixel of a conventional 4T-type CMOS image sensor will be described.

FIG. 1 is a view illustrating an equivalent circuit of a related art 4T-type CMOS image sensor, and FIG. 2 is a layout illustrating a unit pixel of a related art 4T-type CMOS image sensor.

Referring to FIG. 1, a unit pixel 100 of the 4T-type CMOS image sensor includes a photodiode 10 and four transistors.

The four transistors include a transfer transistor 20, a reset transistor 30, a drive transistor 40 and a select transistor 50. Also, a load transistor 60 is electrically connected to an output terminal OUT of the unit pixel 100.

The reference FD is a floating diffusion region, the reference Tx is the gate voltage of the transfer transistor 20, the reference Rx is the gate voltage of the reset transistor 30, the reference Dx is the gate voltage of the drive transistor 40 and the reference Sx is the gate voltage of the select transistor 50.

Referring to FIG. 2, in the unit pixel of the related art 4T-type CMOS image sensor, an active region is defined on the semiconductor substrate with a device isolation layer formed on the substrate except for the active region. One photodiode PD is formed in a wider portion of the active region and gate electrodes 23, 33, 43 and 53 of four transistors are formed overlapping the remaining portion of the active region.

That is, the transfer transistor 20 is formed by the gate electrode 23, the reset transistor 30 is formed by the gate electrode 33, the drive transistor 40 is formed by the gate electrode 43 and a select transistor 50 is formed by the gate electrode 53.

Here, impurity ions are implanted into portions of the active region under a portion of each of the gate electrodes 23, 33, 43 and 53 to form a source/drain region (S/D) of each transistor.

FIG. 3 is a cross-sectional view of a CMOS image sensor according to a related art.

Referring to FIG. 3, the CMOS image sensor includes: a P⁻-type epitaxial layer 62 formed on a P⁺⁺-type semiconductor substrate 61 including an active region having a photodiode region and a transistor region and a device isolation region; a device isolation layer 63 formed in the device isolation region in order to define the active region of the semiconductor substrate 61; a gate electrode 65 formed on the active region of the semiconductor substrate 61 with a gate insulating layer 64 interposed between the semiconductor substrate 61 and the gate electrode 65; a low concentration n-type diffusion region 67 formed in the photodiode region at one side of the gate electrode 65; sidewall insulating layers 68 formed on side surfaces of the gate electrode 65; a high concentration n⁺-type diffusion region (a floating diffusion region) 69 formed in the transistor region of a second side of the gate electrode 65; and a P⁰-type diffusion region 72 formed on the low concentration n-type diffusion region 67 of the semiconductor substrate 61.

FIGS. 4A and 4B are cross-sectional views illustrating electron flow according to an operation of a transfer transistor in a CMOS image sensor according to the related art.

Referring to FIG. 4A, when a turn-on signal is applied to the gate electrode 65 of the transfer transistor, electrons generated by light in the low concentration n-type diffusion region (the photodiode region PD) 67 are transmitted to the high concentration n⁺-type diffusion region (the floating diffusion region) 69 as illustrated in FIG. 4B.

However, when a fixed quantity of light is incident according to a capacitance of the photodiode region or the floating diffusion region, the capacitance of the floating diffusion region is saturated and stops further response.

In the related art CMOS image sensor, there is a problem as described below.

That is, when a fixed quantity of light is incident according to a capacitance of the photodiode region or the floating diffusion region, the capacitance of the floating diffusion region is saturated to stop a further response.

### BRIEF SUMMARY

Accordingly, embodiments of the present invention are directed to a CMOS image sensor extending a dynamic range of a floating diffusion region and a method for fabricating the same.

To achieve these objects and other advantages and in accordance with the purpose of the invention, as embodied and broadly described herein, there is provided a CMOS image sensor including: a semiconductor substrate having a photodiode region and a transistor region defined therein; first and second gate electrodes formed on the photodiode region with a gate insulating layer interposed therebetween, the first and second gate electrodes spaced a predetermined interval from each other; a first conductivity type diffusion region formed in the photodiode region at both sides of the first and second gate electrodes; spacer insulating layers formed on sidewalls of the first and second gate electrodes; and a floating diffusion region formed in the transistor region.

In another aspect of the present invention, there is provided a method of fabricating a CMOS image sensor including: providing a semiconductor substrate having a photodiode region and a transistor region defined therein; forming first and second gate electrodes on the photodiode region of the semiconductor substrate with a gate insulating layer interposed therebetween, the first and second electrodes spaced a predetermined interval from each other; forming a first conductivity type diffusion region in the photodiode region at both sides of the first and second gate electrodes; forming spacer insulating layers on sidewalls of the first and second gate electrodes; and forming a floating diffusion region in the transistor region of the semiconductor substrate.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIG. 1 is a view illustrating an equivalent circuit of a related art 4T-type CMOS image sensor.

FIG. 2 is a layout illustrating a unit pixel of a related art 4T-type CMOS image sensor.

FIG. 3 is a cross-sectional view of a CMOS image sensor according to a related art.

FIGS. 4A and 4B are cross-sectional views illustrating electron flow according to an operation of a transfer transistor in a CMOS image sensor according to a related art.

FIG. 5A is a layout illustrating a unit pixel of a 4T-type CMOS image sensor according to an embodiment of the present invention.

FIG. 5B is a cross-sectional view of a CMOS image sensor taken along line VI-VI′ of FIG. 5A.

FIGS. 6A to 6F are cross-sectional views illustrating a method of fabricating a CMOS image sensor according to an embodiment of the present invention.

FIG. 7 is a cross-sectional view for explaining an operation of a CMOS image sensor according to an embodiment of the present invention.

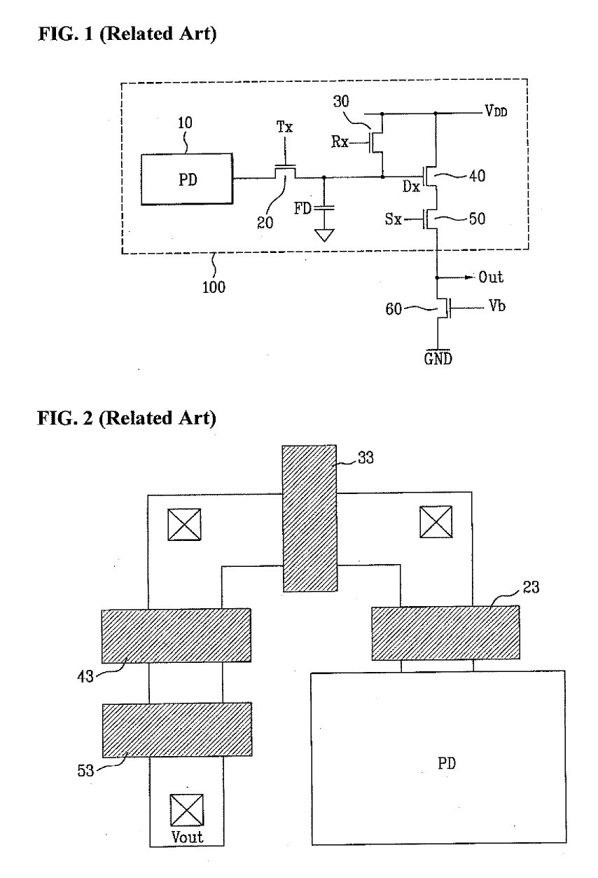

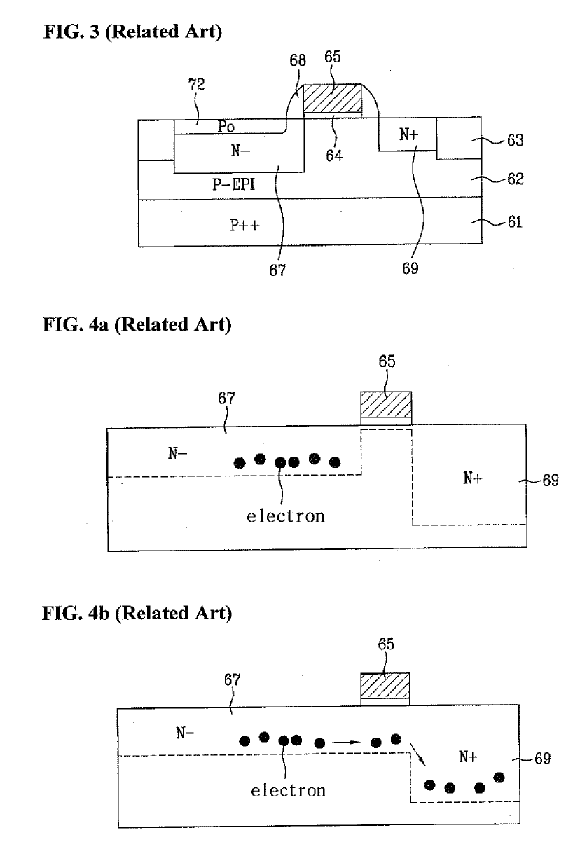

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a CMOS image sensor and a method for fabricating the same according to an embodiment of the present invention will be described in detail with reference to the accompanying drawings.

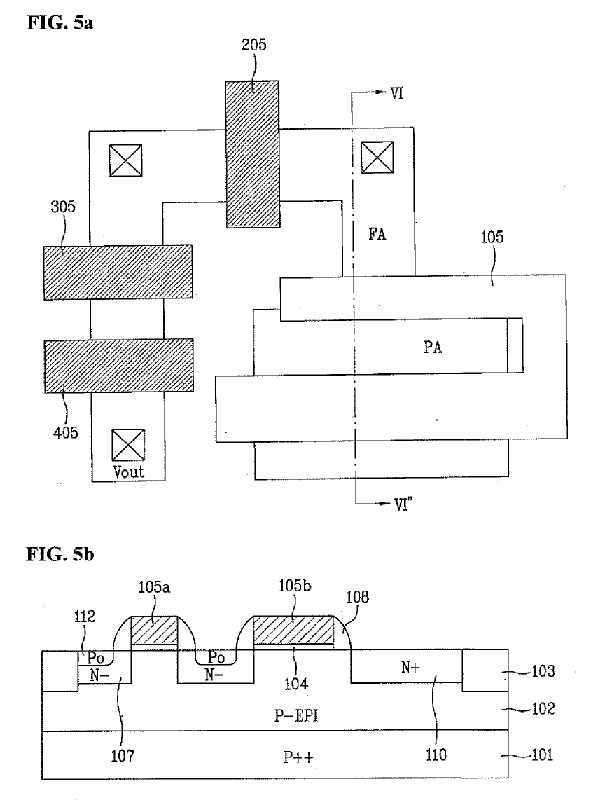

FIG. 5A is a layout illustrating a unit pixel of a 4T-type CMOS image sensor according to an embodiment of the present invention, and FIG. 5B is a cross-sectional view of a CMOS image sensor taken along line VI-VI′ of FIG. 5A.

Referring to FIG. 5A, an active region can be defined on the semiconductor substrate with a device isolation layer formed on the semiconductor substrate except for at the active region. A photodiode PD can be formed in a wide portion of the active region and gate electrodes 105, 205, 305 and 405 of four transistors can be formed overlapping portions of the active region.

That is, a transfer transistor can be formed by the gate electrode 105, a reset transistor can be formed by the gate electrode 205, a drive transistor can be formed by the gate electrode 305 and a select transistor can be formed by the gate electrode 405.

Here, impurity ions can be implanted into portions of the active region except under a portion of each of the gate electrodes 105, 205, 305 and 405 of each transistor to form a source/drain region (S/D) of each transistor.

In a preferred embodiment, the gate electrode 105 of the transfer transistor can be formed on the photodiode region of the active region in a “⊂” shape.

As seen in FIG. 5B, the CMOS image sensor can include; a P⁻-type epitaxial layer 102 formed on a P⁺⁺-type conductivity semiconductor substrate 101 with an active region having a photodiode region and a transistor region and a device isolation region defined therein; a device isolation layer 103 formed in the device isolation region; a gate insulating layer 104 interposed between the active region of the semiconductor substrate 101 and a gate electrode to form first and second gate electrodes 105a and 105b; a low concentration n-type diffusion region 107 formed in the photodiode region including between the first and second gate electrodes 105a and 105b; spacer insulating layers 108 formed on sidewalls of the first and second gate electrodes 105a and 105b; a high concentration n⁺-type diffusion region (a floating diffusion region) 10 formed in the transistor region at a side of the second gate electrode 105b; and a P⁰-type diffusion region 112 formed on the low concentration n-type diffusion region 107.

In an embodiment, widths (that is, a channel length) of the first and second gate electrodes 105a and 105b are different from each other.

Also, a voltage applied to the first and second gate electrodes 105a and 105b to turn the electrode on can be applied with a different voltage from each other according to according to a quantity of light.

That is, only one electrode can be turned on or both electrodes can be turned on of the first and second gate electrodes 105a and 105b. Output signals can be different for when the two electrodes are turned on and when only one electrode is turned on.

In a specific embodiment, the first gate electrode 105a is formed overlying a portion of the photodiode region and the second gate electrode 105b is formed on the boundary of the photodiode region and the transistor region, crossing thereover.

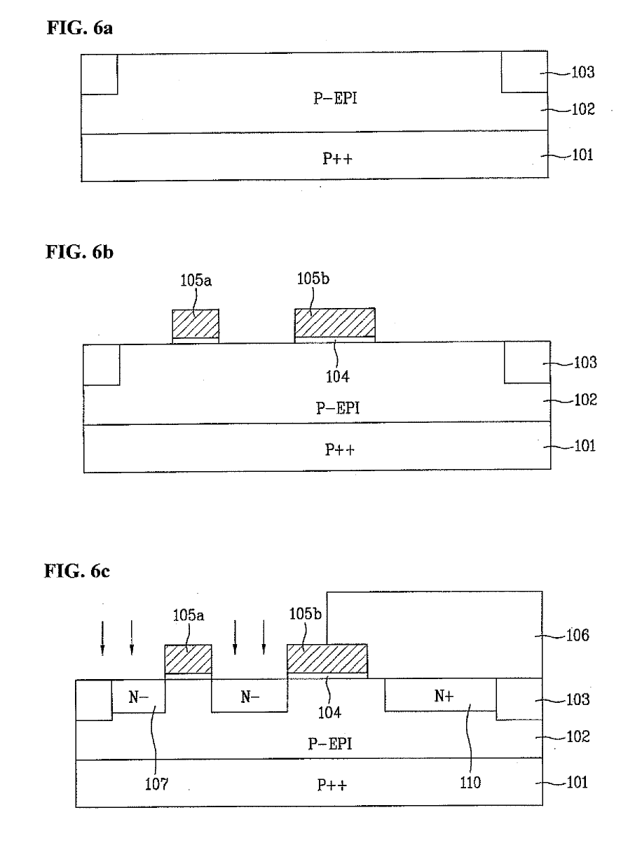

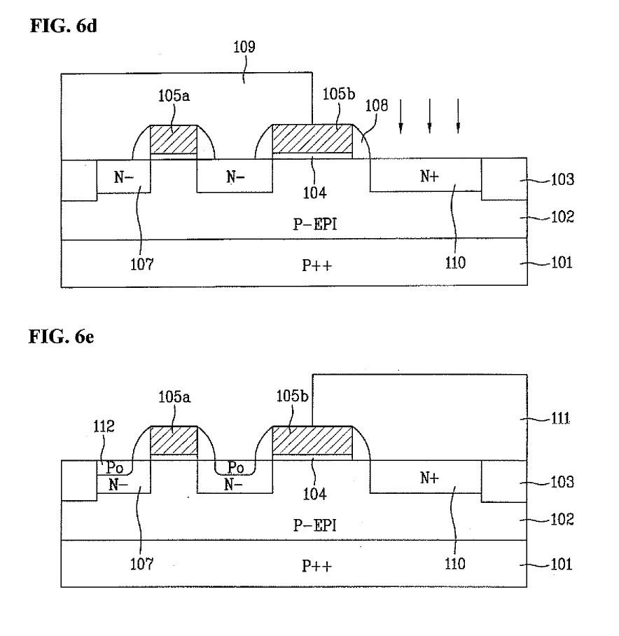

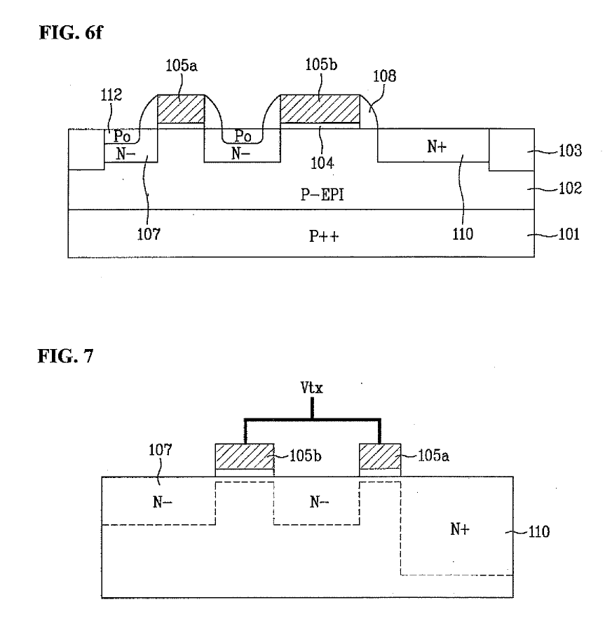

FIGS. 6A through 6F are cross-sectional views illustrating a method of fabricating a CMOS image sensor according to an embodiment of the present invention.

Referring to FIG. 6A, a low concentration P⁻-type epitaxial layer 102 can be formed using an epitaxial process on a high concentration P⁺⁺-type semiconductor substrate 101.

An active region and a device isolation region can be defined in the semiconductor substrate 101. A device isolation layer 103 can be formed in the device isolation region using, for example, a shallow trench isolation (STI) process.

Although not shown in the drawings, a method for forming the device isolation layer 103 will be described in below.

A pad oxide layer, a pad nitride layer and a tetra ethyl ortho silicate (TEOS) oxide layer are sequentially formed on the semiconductor substrate 101, and a photoresist layer is formed on the TEOS oxide layer.

The photoresist layer is patterned using a mask defining the active region and the device isolation region through exposure and development processes. Here, the photoresist layer of the device isolation region is removed.

The pad oxide layer, the pad nitride layer and the TEOS oxide layer of the device isolation region are selectively removed using the patterned photoresist layer as a mask.

A portion of the semiconductor substrate corresponding to the device isolation region is etched to a predetermined depth so as to form a trench, using the patterned pad oxide layer, pad nitride layer, and TEOS oxide layer as a mask. Thereafter, the photoresist layer is completely removed.

An inner portion of the trench is filled with an insulating material to form the device isolation layer 103. Thereafter, the pad oxide layer, the pad nitride layer and the TEOS oxide layer are removed.

Referring to FIG. 6B, a gate insulating layer 104 and a conductive layer, for example, a high concentration poly-crystal silicon layer, can be sequentially deposited on an entire surface of the P⁻type epitaxial layer 102.

The gate insulating layer 104 may be formed through a thermal oxidation process or a chemical vapor deposition (CVD) process.

Then, the conductive layer and the gate insulation layer 104 can be selectively removed to form a gate electrode including first and second gate electrodes 105a and 105b.

The first and second gate electrodes 105a and 105b can be the gate electrode of a transfer transistor.

Referring to FIG. 6C, a first photoresist layer 106 can be coated on an entire surface of the semiconductor substrate 101 including the first and second gate electrodes 105a and 105b, and then selectively patterned so as to expose each of photodiode regions by exposure and development processes.

Next, a low concentration of second conductive type (n⁻ type) impurity ions can be implanted into the epitaxial layer 102 using the patterned first photoresist layer 106 as a mask to form an n⁻ type diffusion region 107.

Referring to FIG. 6D, the first photoresist layer 106 can be removed, and then an insulating layer can be formed on the entire surface of the semiconductor substrate 101 including the first and second gate electrodes 105a and 105b. Thereafter, an etch-back process can be performed to form spacer insulating layers 108 on sidewalls of the first and second gate electrodes 105a and 105b.

Subsequently, a second photoresist layer 109 can be coated on the entire surface of the semiconductor substrate 101 including the first and second gate electrodes 105a and 105b, and then patterned so as to cover the photodiode regions and expose source/drain regions of the each transistor through exposure and development processes.

Next, a high concentration of second conductive type (n+ type) impurity ions can be implanted into the exposed source/drain regions using the patterned second photoresist layer 109 as a mask to form an n+ type diffusion region (floating diffusion region) 110.

Referring to FIG. 6E, the second photoresist layer 109 can be removed. Thereafter, a third photoresist layer 111 can be applied on an entire surface of the semiconductor substrate 101, and then patterned so as to expose each photodiode region through exposure and development processes.

Subsequently, first conductive type (p⁰ type) impurity ions are implanted into the epitaxial layer 102 where the n⁻ type diffusion region 107 is formed can be using the patterned third photoresist layer 111 as a mask to form a p⁰ type diffusion region 112 beneath a surface of the epitaxial layer 102.

Referring to FIG. 6F, the third photoresist layer 111 can be removed, and a heat treatment can be performed on the semiconductor substrate 101 to diffuse each impurity diffusion region.

Although the following process is not shown in the drawings, a plurality of metal wirings of an interlayer insulating layer can be formed on the entire surface of the semiconductor substrate 101, and a color filter layer and a microlens can be formed to complete the fabrication of the image sensor.

FIG. 7 is a cross-sectional view for explaining an operation of a CMOS image sensor according to an embodiment of the present invention.

As illustrated in FIG. 7, the photodiode region PD is divided into two regions using first and second gate electrodes 105a and 105b each having a different width (channel area). Thus, when a small amount of light is incident the photodiode, the first and second gate electrodes 105a and 105b are both turned on to increase the number of electrons that can be transmitted to the floating diffusion region 110. When a large amount of light is incident the photodiode, only one electrode is turned on to decrease the number of electrons. Therefore, reaction characteristics according to the small or large amount of light can be improved by modifying amplification ratio of the applied voltages, respectively.

That is, in the case that the amount of light is small, a high voltage is applied to the transfer transistor (Vₜₓ) to apply a turn-on voltage to the first and second gate electrodes, thereby increasing the number of electrons to be transmitted to the floating diffusion region FD. Therefore, sensitivity in response to the small amount of light can be increased.

In the case that the amount of light is large, a low voltage is applied to the transfer transistor (Vₜₓ) to apply the turn-on voltage to only the first gate electrode 105a having a relatively smaller width (channel length) thereby decreasing the number of electrons to be transmitted to the floating diffusion region FD in order to prevent insensitivity to the much larger amount of light caused by saturating the floating diffusion region.

In a specific embodiment of the present invention, the threshold voltage of the first gate electrode 105a is 0.5 V and the threshold voltage of the second gate electrode 105b is 0.1 V.

As described above, a method of fabricating a CMOS image sensor according to the present invention has following effects.

First, the gates of the transfer transistor are formed as dual gate transistor structure to increase a dynamic range of the floating diffusion region responding to light, thereby improving operational characteristics of the image sensor.

Second, the gates of the transfer transistor are formed as dual gate transistor structure to decrease leakage current from the photodiode region to the floating diffusion region.

Third, the range of use of the image sensor is extended by increasing the operation range of the floating diffusion region and decreasing the leakage current of the image sensor

It will be apparent to those skilled in the art that various modifications and variations can be made in the present invention. Thus, it is intended that the present invention covers the modifications and variations of this invention provided they come within the scope of the appended claims and their equivalents.

I claim:

1. A complementary metal oxide semiconductor image sensor, comprising:
a semiconductor substrate having a photodiode region and a transistor region defined therein;
a gate electrode comprising first and second gate electrodes formed on the photodiode region of the semiconductor substrate with a gate insulating layer interposed therebetween;
a first conductivity type diffusion region formed in portions of the photodiode region at a first side of the first gate electrode and between the first and second gate electrodes;
spacer insulating layers formed on sidewalls of the first and second gate electrodes; and
a floating diffusion region formed in the transistor region.

2. The CMOS image sensor according to claim 1, further comprising a second conductivity type diffusion region formed on the first conductivity type diffusion region.

3. The CMOS image sensor according to claim 1, wherein widths of the first and second gate electrodes are different from each other.

4. The CMOS image sensor according to claim 1, wherein channel lengths under the first and second gate electrodes are different from each other.

5. The CMOS image sensor according to claim 1, wherein both the first and second gate electrodes are capable of being turned on by a voltage applied to the gate electrode where an amount of incident light is low, and the second gate electrode is capable of being turned on without the first gate electrode being turned on by a second voltage applied to the gate electrode when the amount of incident light is high.

6. The CMOS image sensor according to claim 1, wherein the first gate electrode is formed overlying a portion of the photodiode region and the second gate electrode is formed at a boundary between the photodiode region and the transistor region.

7. A method of fabricating a CMOS image sensor, comprising:
providing a semiconductor substrate having a photodiode region and a transistor region defined therein;
forming a gate electrode comprising first and second gate electrodes on the photodiode region of the semiconductor substrate with a gate insulating layer interposed therebetween;
forming a first conductivity type diffusion region in the photodiode region;
forming spacer insulating layers on sidewalls of the first and second gate electrodes; and
forming a floating diffusion region in the transistor region of the semiconductor substrate.

8. The method according to claim 7, further comprising forming a second conductivity type diffusion region on the first conductivity type diffusion region.

9. The method according to claim 7, wherein widths of the first and second gate electrodes are formed different from each other.

10. The method according to claim 7, wherein channel lengths under the first and second gate electrodes are formed different from each other.
